(19) United States
(12) Patent Application Publication
(10) Pub. No.: US 2003/0090862 A1
(43) Pub. Date: May 15, 2003

(54) Rotatable monitor

(76) Inventor: Lin Shen Hsiang, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/082,058

(22) Filed: Feb. 26, 2002

(30) Foreign Application Priority Data
Nov. 9, 2001 (TW) 90219327

(51) Int. Cl. G06F 1/16; H05K 5/00; H05K 7/00

(52) U.S. Cl. 361/681; 248/917; 248/922; 248/923

(57) ABSTRACT

A rotatable monitor has a display section being rotatable laterally for 0-180 degrees and covering on an operative section by its front side or rear side thereof. The rotatable monitor comprises a display section with a pivotal section on bottom thereof; an operative section with a pivotal stage on front side thereof and pivotally connected to the pivotal section. The pivotal section has a pivotal mechanism comprising a movable rack arranged on the display section and a fixed rack arranged on the pivotal section and being pivotal with respect to the movable rack. A rotational shaft is provided between the pivotal stage and the fixed rack. The display section can be locked to or unlocked from the pivotal section by retainers.

### FIELD OF THE INVENTION

The invention relates to a rotatable monitor, especially to a rotatable monitor with a display section being rotatable laterally for 0-180 degrees and covering on an operative section by its front side or rear side thereof.

### BACKGROUND OF THE INVENTION

The portable electronic devices such as palm computer or notebook computer generally have foldable flat monitor for convenience.

However, in above-mentioned portable electronic devices, the foldable flat monitor thereof can only be opened or closed such that the foldable flat monitor should be rotated 180 degree to display for opposite people. Moreover, in case that the foldable flat monitor is touch panel or input through a light pen, the foldable flat monitor should be held by another hand for smooth operation, which is inconvenient.

FIG. 1 shows one conventional portable electronic device, which will exemplifies three main disadvantages in prior art:

1. The notebook computer has a display section 1 with a display monitor and an operative section 8 with keyboard. The operative section 8 has a plurality of coaxial pivotal stages 81 pivotally connected to bottom end of the display section 1, whereby the display section 1 can be opened or closed with respect to the operative section 8. However, the display section 1 cannot be rotated laterally to display for opposite people.

2. In case that the display section 1 is a touch panel, the pivotal stages 81 are generally rotated freely with respect to the display section 1. Therefore, another hand is needed to hold the display section 1 to prevent it from falling.

3. In case that the display section 1 is input through a light pen, the input task is inconvenient due to a height offset is present between the display section 1 and the operative section 8.

Improvements have been made for the display of the portable electronic devices. However, only the first problem can be solved and the second and the third problem are pending.

### SUMMARY OF THE INVENTION

It is an object of the present invention to provide a rotatable monitor, which has a display section pivotally connected to a pivotal section through a pivotal shaft. The pivotal section is pivotally connected to a pivotal stage of an operative section such that the display section can be opened with respect to the pivotal stage and has azimuth rotation with respect to the pivotal shaft by 0-180 degree. The display section can be flatly laid on the operative section with its display screen facing upward to facilitate the input through finger touch or input stylus.

It is another object of the present invention to provide a rotatable monitor, wherein the display section pivotally and the pivotal section thereof can be locked by retainers to retain the display section either it is rotated 0 or 180 degree.

It is still another object of the present invention to provide a rotatable monitor having a means to confine the rotation angle of the display section to be within 180 degree to prevent twist of power and signal cables.

It is still another object of the present invention to provide a rotatable monitor with a locking mechanism to lock the display section on the operative section either it faces up or faces down.

To achieve above object, the present invention provides a rotatable monitor with a display section being rotatable laterally for 0-180 degrees and covering on an operative section by its front side or rear side thereof. The rotatable monitor comprises a display section with a pivotal section on bottom thereof; an operative section with a pivotal stage on front side thereof and pivotally connected to the pivotal section. The pivotal section has a pivotal mechanism comprising a movable rack arranged on the display section and a fixed rack arranged on the pivotal section and being pivotal with respect to the movable rack. A rotational shaft is provided between the pivotal stage and the fixed rack. The display section can be locked to or unlocked from the pivotal section by retainers.

The various objects and advantages of the present invention will be more readily understood from the following detailed description when read in conjunction with the appended drawing, in which:

### BRIEF DESCRIPTION OF DRAWING

FIG. 1 shows the perspective view of prior art monitor;

FIG. 2 shows an exploded view of a display section and a pivotal section according to the present invention;

FIG. 3 shows an enlarged exploded view of the pivotal section in FIG. 2;

FIG. 3A shows a partially perspective view of the pivotal shaft in FIG. 3;

FIG. 4 shows a perspective view of the display section and the pivotal section according to the present invention;

FIG. 4A shows a sectional view of the operative section and the pivotal section according to the present invention;

FIG. 4B shows a sectional view along line 4B-4C in FIG. 4A;

FIG. 4C shows a sectional view in FIG. 4A wherein the retainers are moved;

FIG. 5 shows an exploded view of the locking mechanism in the operative section;

FIG. 6 shows a perspective view of the locking mechanism in the operative section;

FIG. 6A shows another perspective view of the locking mechanism in the operative section;

FIG. 7 shows a top view of the locking mechanism in the operative section;

FIG. 8 shows a notebook computer adopting the inventive rotatable monitor and in a closed state;

FIG. 9 shows that the display section of the notebook computer in FIG. 8 is opened;

FIG. 10 shows that the opened display section of the notebook computer is rotated in azimuth angle by 45 degree;

FIG. 11 shows that the opened display section of the notebook computer is rotated in azimuth angle by 180 degree; and

FIG. 12 shows that the opened display section of the notebook computer is laid on the operative section.

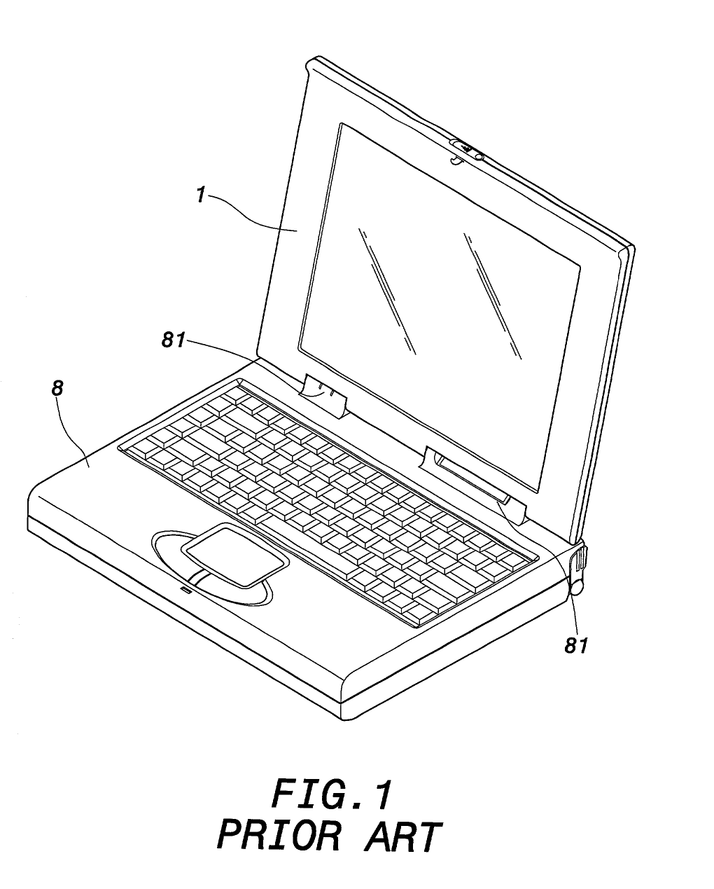

### DETAILED DESCRIPTION OF THE INVENTION

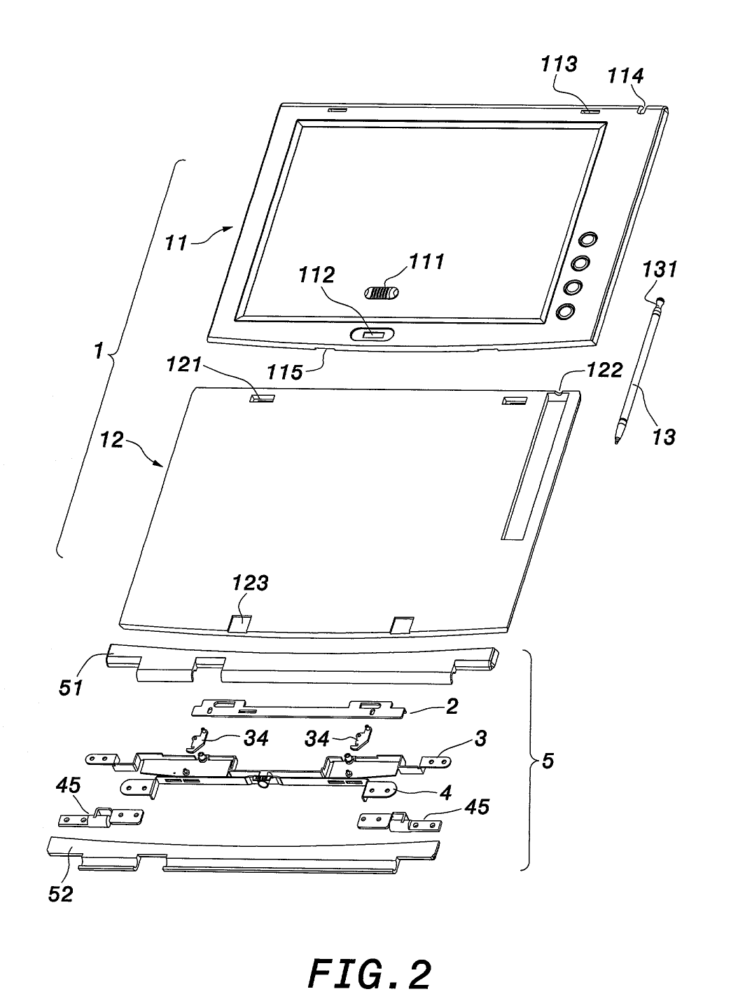

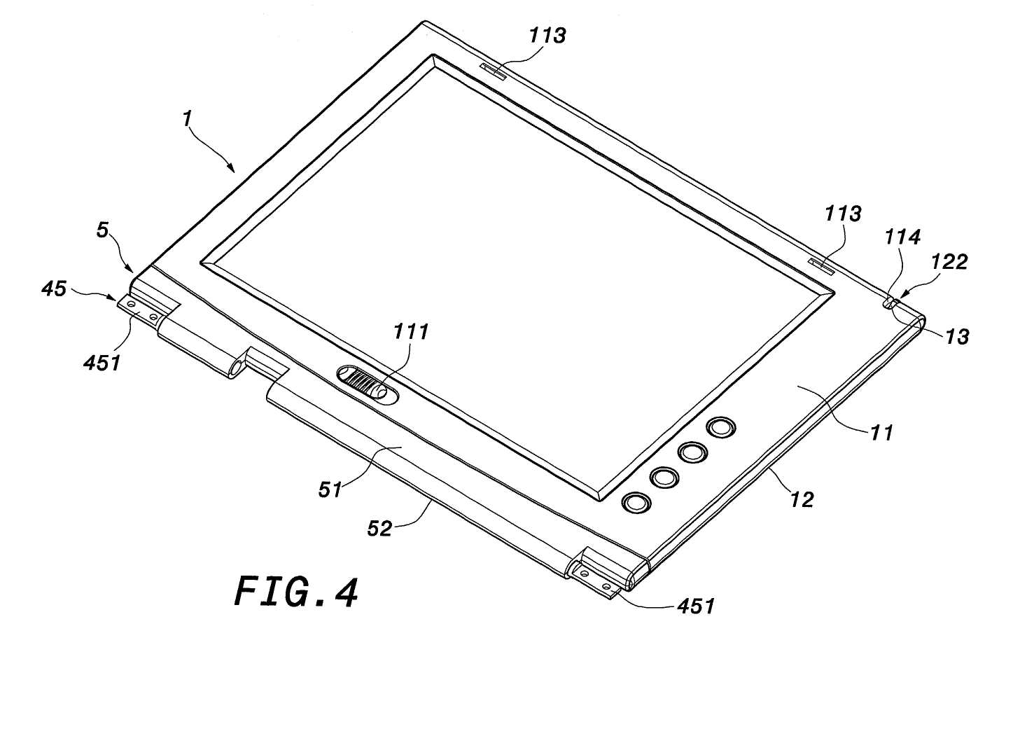

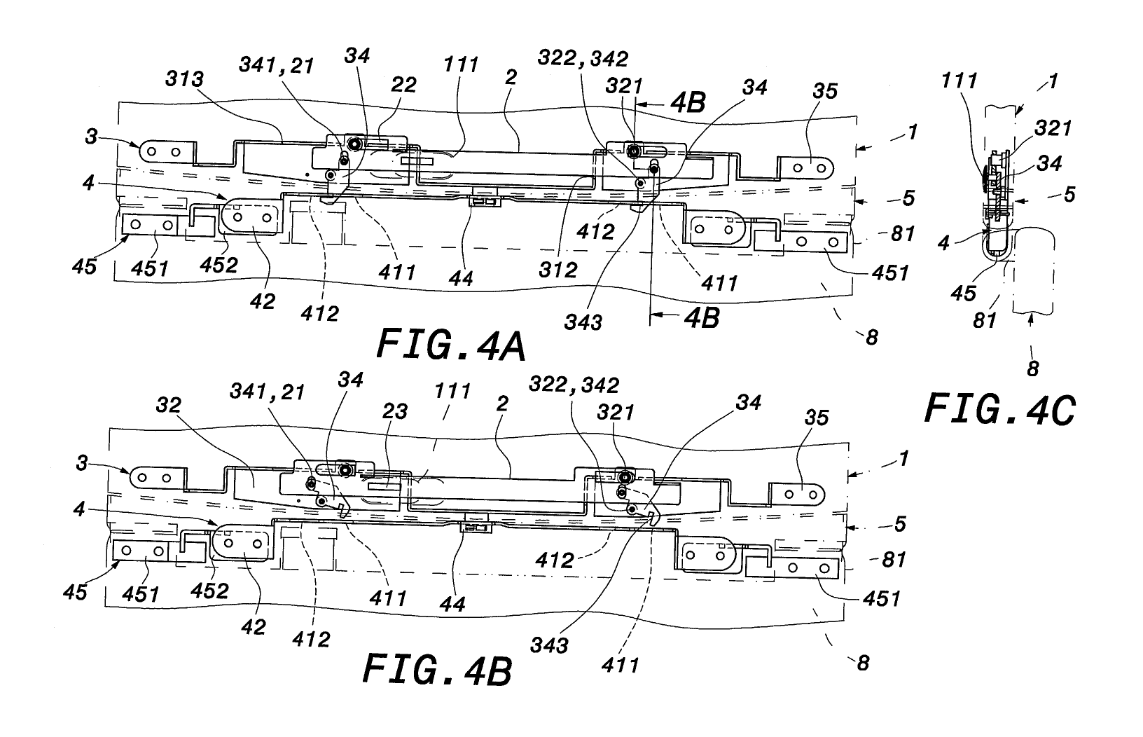

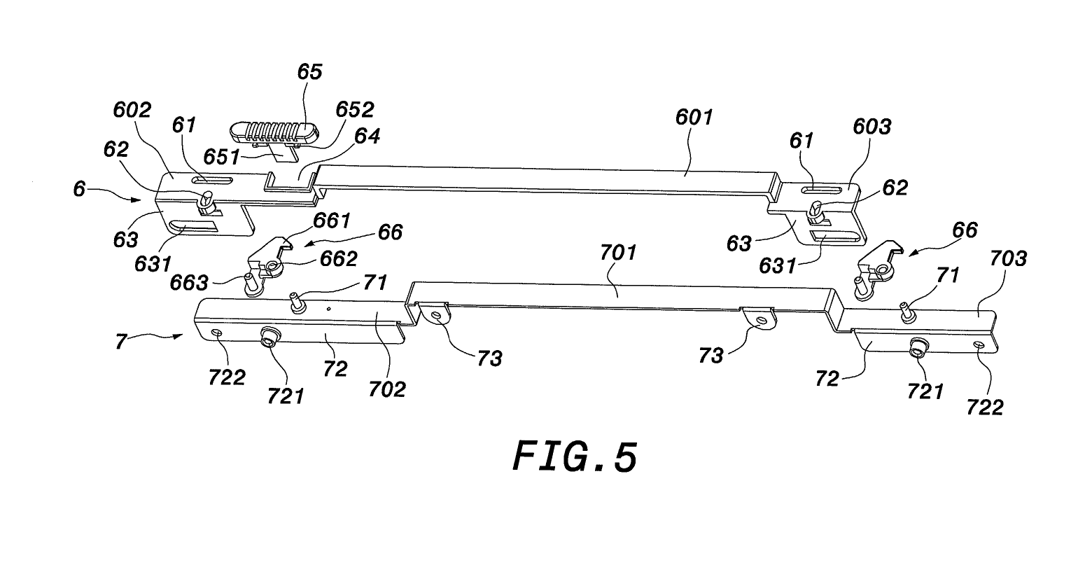

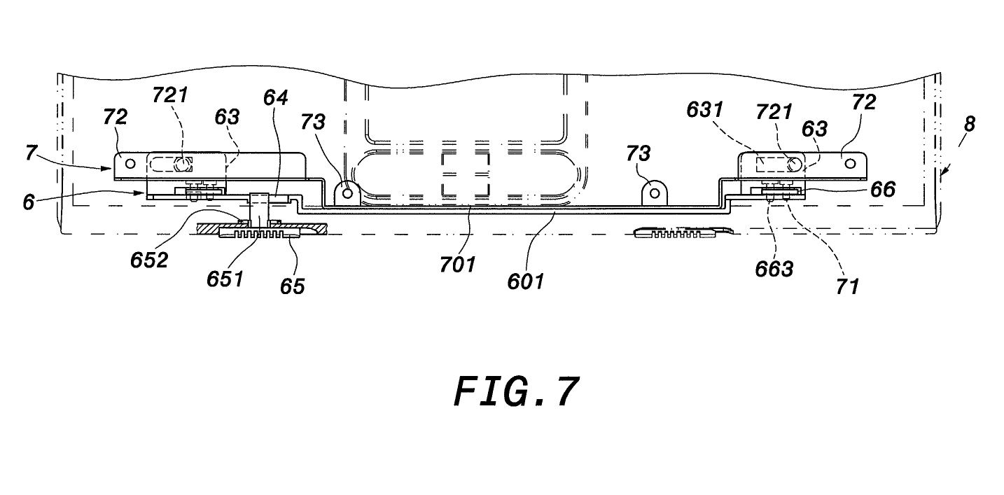

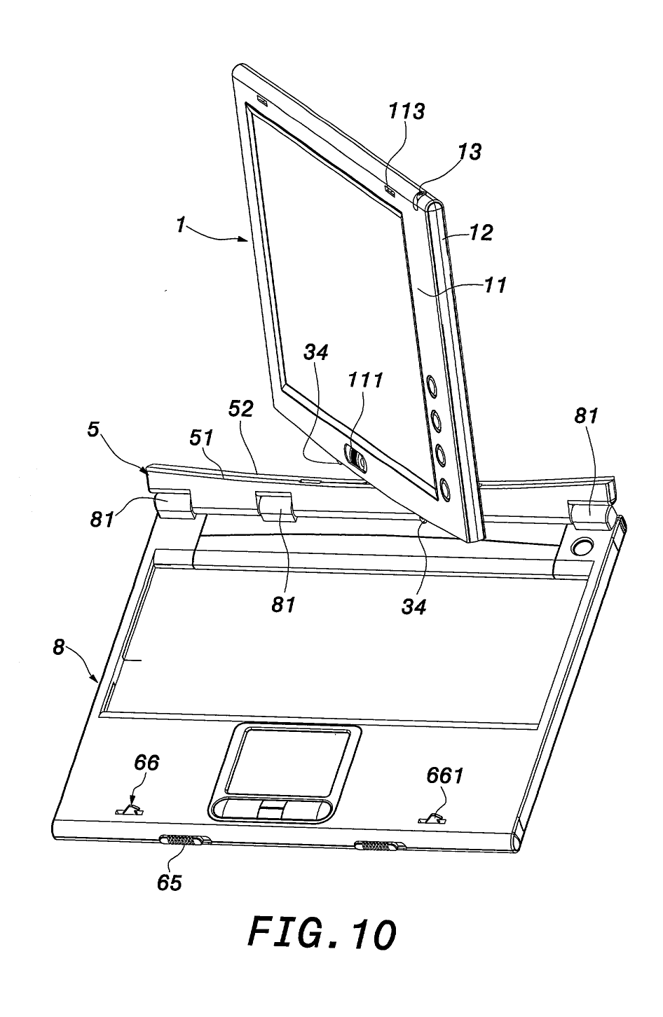

FIG. 2 shows a display section 1 and a pivotal section 5 according to the present invention, wherein the pivotal section 5 has a pivotal mechanism. FIG. 4 shows a perspective view after the display section 1 and the pivotal section 5 are assembled and FIG. 5 shows a locking mechanism according to the present invention. As shown in FIG. 7, the locking mechanism can be arranged in an operative section 8 to lock the display section 1 on the operative section 8. FIG. 10 shows a notebook computer provided with the pivotal section 5 having the pivotal mechanism and the locking mechanism, whereby the display section 1 of the notebook computer has 0-180 degree rotation. The display section 1 of the notebook computer has display means such as LCD or CRT.

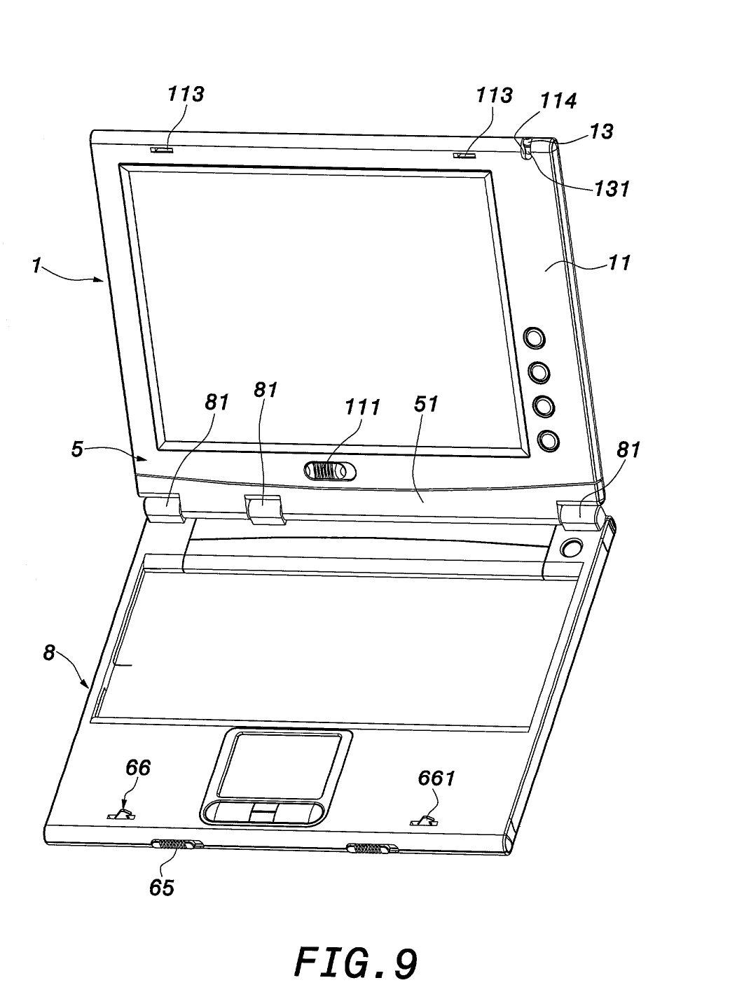

With reference to FIGS. 2 and 4, the display section 1 is composed of an outer shell 12 and an inner shell 11 with a display panel on inner face thereof, wherein the outer shell 12 constitutes a rear side of the display section land the inner shell 11 constitutes a front side of the display section 1. The inner shell 11 has two locking slots 113 symmetrically arranged on topside thereof. The display section 1, after the outer shell 12 is assembled with the inner shell 11, has an insertion slot 122 for receiving an input pen 13 such as a light pen. The inner shell 11 has a dent 114 corresponding to the insertion slot 122 to expose a tail end of the pen 13 as shown in FIG. 9. The inner shell 11 and the outer shell 12 have receiving spaces 115 and 123 on bottom ends thereof. The pivotal section 5 is arranged below the display section 1 and has mating inner ornamental plate 51 and outer ornamental plate 52 and a pivotal mechanism between the two ornamental plates.

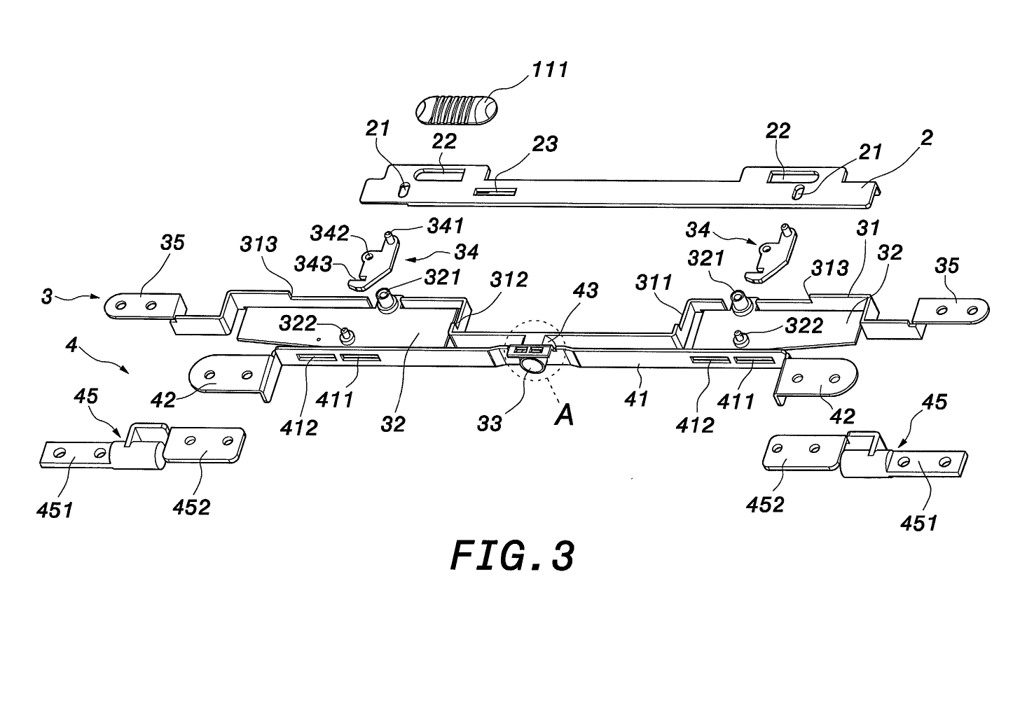

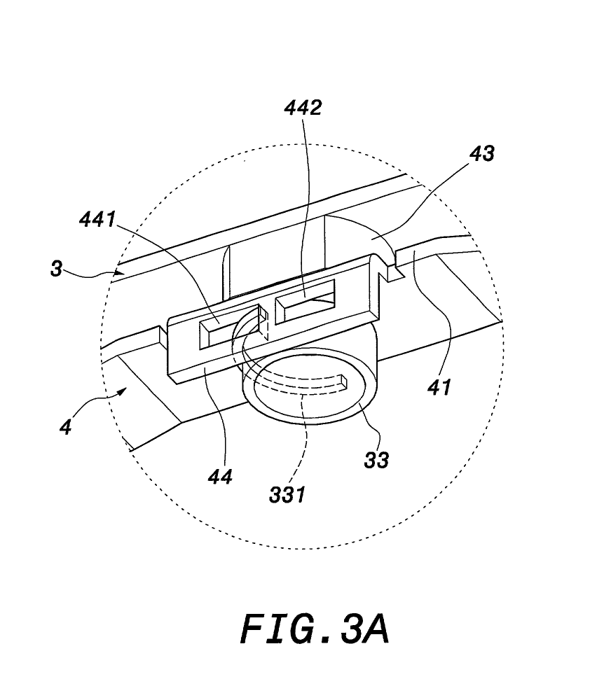

FIG. 3 shows the exploded view of the pivotal mechanism, which comprises a link beam 2, a movable rack 3 pivotally connected to a fixed rack 4, two retainer 34 and two shafts pivotally connected to the pivotal stages 81, as shown in FIGS. 4 and 4A.

The link beam 2 has a driving hole 21 and an elongated sliding slot 22 on each end thereof. The link beam 2 further has an elongated retaining slot 23 near the sliding slot 22 on left end thereof.

The movable rack 3 is integrally formed by bending a beam 31 and having a pivotal center and two shoulders. Each shoulder is bent and has a plate 32 therein and a locking tab 35 on distal end thereof. Each shoulder has a cutaway 311 with height offset with respect to the pivotal center and uncut portion of the shoulders, thereby forming stairs 312 and 313 to restrict the sliding of the link beam 2. The plate 32 has a guiding post 321 slidable within the elongated sliding slot 22 and a pivot 322 pivotally connected to the pivotal hole 342 of the retainer 34.

The fixed rack 4 has a beam 41 with a pivot thereon and two shoulder portions. Each shoulder portion has an insertion silt 411 and an adjacent slit 412 fit with corresponding locking recess 343 of the retainer 34 and a retaining tab 42 on distal end thereof.

As shown in FIG. 3A, the fixed rack 4 has a fixed outer shaft 43 projecting upward and the movable rack 3 has a movable inner shaft 33 projecting downward into the fixed outer shaft 43 and exposing out of the fixed outer shaft 43, whereby the fixed rack 4 and the movable rack 3 can be pivoted through the movable inner shaft 33 and the fixed outer shaft 43. The beam 41 has a retaining plate 44 extending from front side thereof and having a left opening 441 and a right opening 442, the movable inner shaft 33 has a semi-annulus retaining rib 331 thereon. As shown in FIG. 3A, the rotation of the movable inner shaft 33 is limited to 180 degree wherein one distal end of the semi-annulus retaining rib 331 is abutted to the left opening 441 or the right opening 442 at rotation limit. Therefore, the twist of wire due to overturn can be prevented.

The retainer 34 has a pivotal hole 342 at center thereof and a driving pin 341 and a locking recess 343 on topside and bottom side, respectively. The pivot 322 is fit into the pivotal hole 342 such that the retainer 34 can be rotated with respect to the pivotal hole 342. The driving pin 341 is fit into the driving hole 21. The link beam 2 is slidable between the stairs 312 and 313 such that the two retainers 34 can be moved forward and backward. When the two retainers 34 are moved forward, the locking recess 343 thereof is engaged with the insertion slit 411 as shown in FIG. 4A. The movable rack 3 cannot be rotated with respect to the fixed rack 4. When the two retainers 34 are moved backward, the locking recess 343 thereof is not engaged with the insertion slit 411 as shown in FIG. 4C. The movable rack 3 can be rotated with respect to the fixed rack 4.

The pivotal mechanism further comprises a rotation shaft 45 with an outer end 451 and an inner end 452 extending axially in opposite directions and pivotally to each other. The inner ends 452 are assembled to the retaining tabs 42 and within the two ornamental plates 51 and 52, whereby the outer ends 451 expose out of the pivotal section 5 as shown in FIGS. 4 and 4A and are assembled to the pivotal stages 81 of the operative section 8 as shown in FIGS. 4A-4C and FIG. 9. Moreover, the retaining tabs 35 on two ends of the movable rack 3 are locked in the display section 1 and between the two shells 11 and 12 (or on inner walls of the shells 11 and 12). Therefore, the fixed rack 4 is fixed to the pivotal section 5 and not rotatable with the display section 1. Moreover, the outer ends 451 are pivotal with respect to the pivotal stages 81 of the operative section 8 and the pivotal section 5 can be pivoted forward and backward with respect to the pivotal stages 81.

With reference to FIGS. 2 and 3, the inner shell 11 has a slide switch 111 on bottom thereof and movable in the elongated retaining slot 23 through a through hole 112. When the slide switch 111 is moved leftward, the link beam 2 drives the retainers 34 to move backward and the retainers 34 are released from the slots 411 and movable in the spaces 115 and 123. Therefore, the display section 1 is rotatable with respect to the pivotal section 5 as shown in FIG. 10.

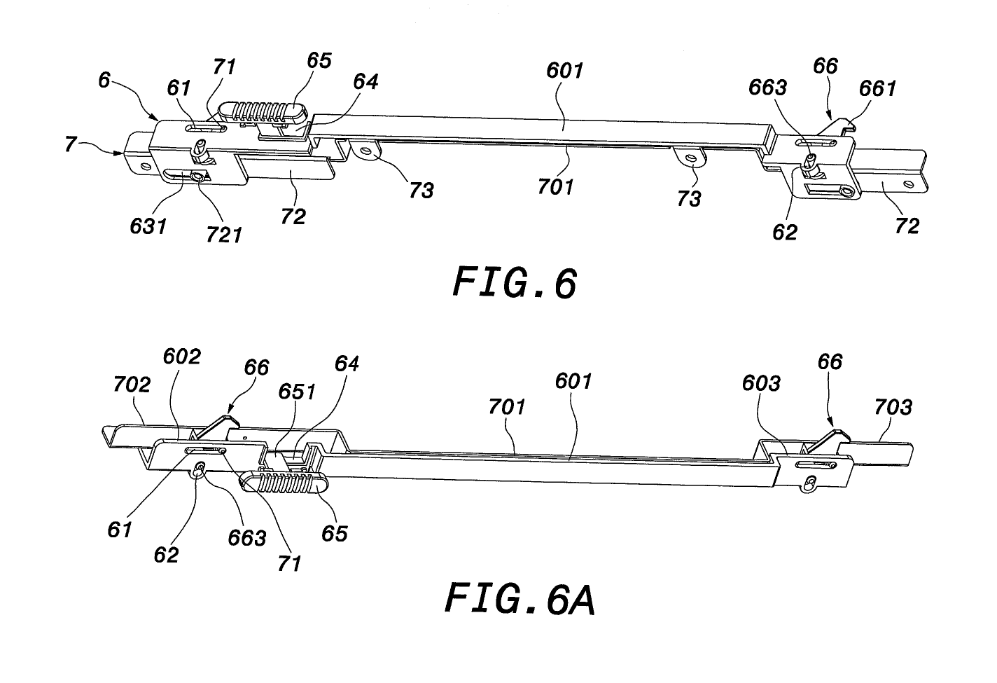

With reference to FIGS. 5 and 6, the locking mechanism comprises a link rack 6, a mounting rack 7, two retainers 66 and a locking switch 65. As shown in FIG. 7, the cross sections of the racks 6 and 7 have projecting portion and the two retainers 66 are provided between the two racks 6 and 7.

The link rack 6 has a projecting section 601 on center thereof and two shoulders 602 and 603 on both ends there of. Each of the shoulders has an actuating hole 62 and an elongated guiding slot 61, and a bottom plate 63 with a bottom slot 631. The left shoulder 602 has a notch 602 for receiving the locking switch 65.

The locking switch 65 has a tongue 651 extending to the notch 64 to drive the link rack 6. As shown in FIG. 7, the locking switch 65 has a clamping section 652 abutting on inner wall of the operative section 8.

The mounting rack 7 has a projecting section 701 on center thereof and two shoulders 702 and 703 on both ends thereof. The projecting section 701 has two retaining tabs 73 to mount the mounting rack 7 to the operative section 8 as shown in FIG. 7. The two shoulders 702 and 703 have pivotal posts 71 projecting forward and bottom plates 72 with guiding posts 721 and through holes 722 to further retain the mounting rack 7 to the operative section 8 as shown in FIG. 7. The guiding posts 721 are engaged with the bottom slot 631. The pivotal posts 71 are engaged with the pivotal holes 662 of the retainers 66. The projecting section 701 has a length smaller than that of the projecting section 601.

Each of the retainers 66 has a pivotal hole 662 at center thereof and a hook 661 and an actuating pin 663 on topside and bottom side thereof, wherein the pivotal posts 71 are engaged with the pivotal holes 662 and the retainer 66 is pivotal with respect to the pivotal hole 662 thereof.

With reference to FIGS. 6 and 6A, the link rack 6 is at front side and the mounting rack 7 is stacked at rear side and the actuating pins 663 are inserted into the actuating holes 62, the pivotal posts 71 are engaged with the elongated guiding slot 61. The guiding posts 721 are engaged with the bottom slot 631. The link rack 6 can be laterally moved and the elongated guiding slot 61and the bottom slot 631 are driven by the pivotal posts 71 and the guiding posts 721. The locking switch 65 drives the link rack 6 through the tongue 651 thereof.

With reference to FIG. 7, the retainers 66 are projected and in lockable state. The locking switch 65 can be moved rightward to unlock the retainers 66, wherein the tongue 651 drives the notch 64 and the actuating hole 62 drives the actuating pins 663. Therefore, the hook 661 releases from the locking slots 113 or 121.

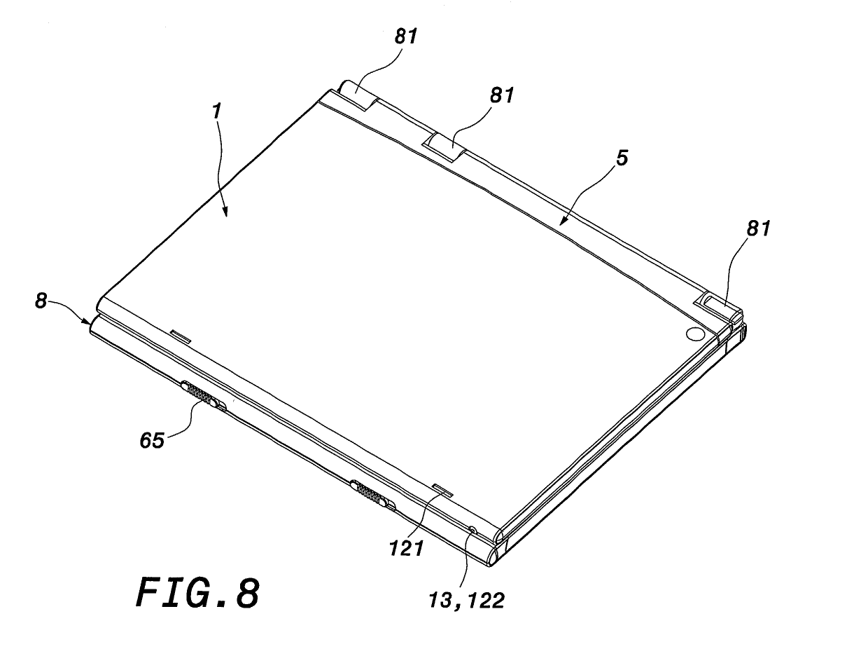

The operation of the pivotal section 5 can be explained through the help of FIGS. 8 to 12.

With reference to FIG. 8, the display section 1 is closed and locked by the retainers 66. The insertion slot 122 on top right side of the display section 1 contains a light pen 13.

With reference to FIG. 9, the locking switch 65 is moved to unlock the retainers 66 from the locking slots 113 and the display section 1 can be opened with respect to the pivotal stage 81. At this time, the retainers of the display section 1 are still locked to the insertion slits 411 of the fixed rack 4 in the pivotal section 5. The display section 1 has a dent 114 to expose the tail 131 of the pen 13 for picking up.

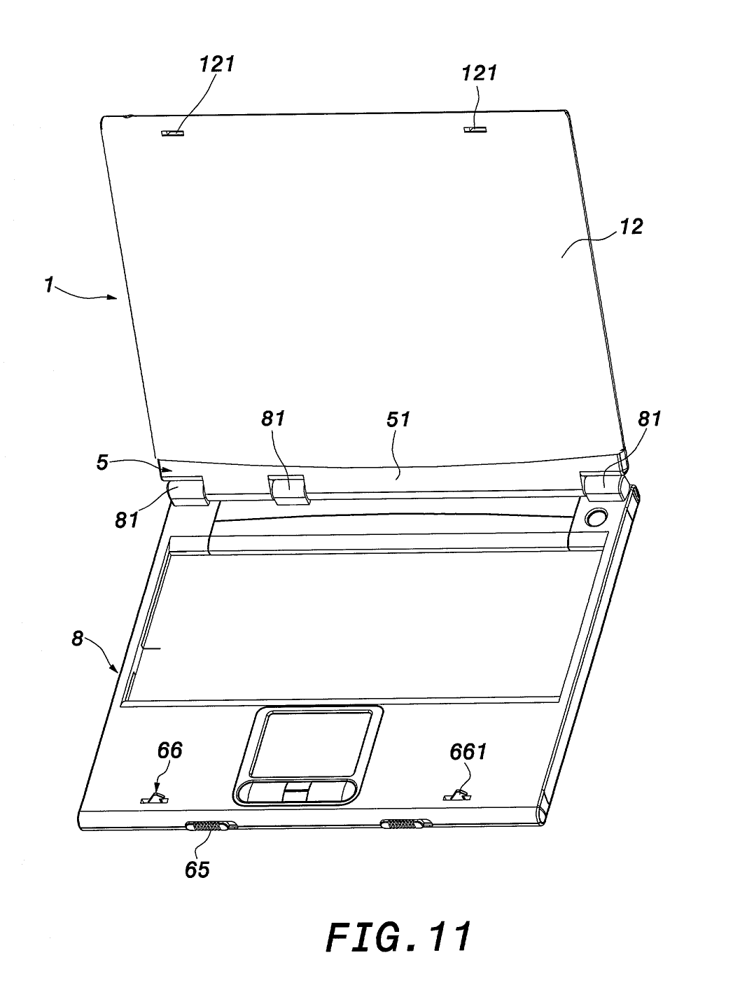

With reference to FIG. 10, the slide switch 111 is moved leftward to drive the link beam 2 and the link beam 2 moves the retainers 34 to release from the insertion slits 411 of the fixed rack 4 in the pivotal section 5, as shown in FIG. 4C. The display section 1 is no longer locked to the fixed rack 4 in the pivotal section 5 and can be freely rotated. After the display section 1 is rotated to 180 degree as shown in FIG. 11, the outer shell 12 is aligned with the inner ornamental plate 51, and the locking slots 121 on the backside of the display section 1 are corresponding to the retainers 66. Similar to the way shown in FIG. 4A, the retainers 34 are locked into the adjacent slits 412 and the display section 1 is again fixed to the pivotal section 5. It should be noted that the retainers 34 shown in FIG. 4A are locked into the slits 411 on right side with hook end facing the left side, the retainers 34 in FIG. 11 (not clearly shown) are locked into the slits 412 on left side with hook end facing the right side.

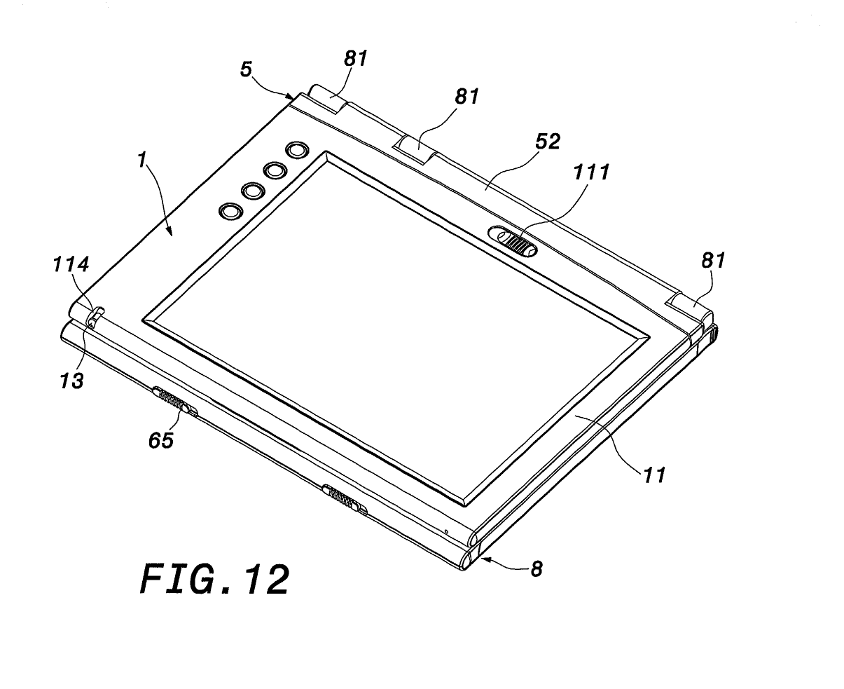

With reference to FIG. 12, the display section 1 is rotated with respect to the pivotal stage 81 and again covers on the operative section 8. At this time, the 121 on the backside of the display section 1 are locked by the retainers 66. Therefore, the display section 1 can be rotated 180 degree to display its screen to opposite people and can be laid on the operative section 8 for facilitating the input through light pen 13.

To sum up, the rotatable monitor of the present invention has following advantages:

1. The provision of the pivotal section 5 separates the rotation in polar-angle direction from the rotation in azimuth-angle direction for the display section 1 to provide flexible display.

2. The pivotal section 5 has robust structure and reliable operation.

3. The display section 1 has only 180 degree rotation swing in azimuth-angle direction to prevent twist of signal line and power line.

4. By operating the slide switch 111, the display section 1 can be locked to or unlocked from the pivotal section 5, the display section 1 can be rotated to show its content to opposite people.

5. As shown in FIG. 12, the display section 1 can be flatly laid on the operative section 8 with its displayed content facing upward. This is suitable for input through finger touch or light pen. Moreover, the display section 1 can be locked by the retainers 66 either on its front side or back side.

6. The present invention is applicable to any electronic products with display monitor such as palm computer, notebook computer and electronic dictionary. Moreover, the display monitor can be ordinary monitor, touch panel or monitor input through input stylus.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim

1. A rotatable monitor comprising
a display section with a pivotal section on bottom thereof;
an operative section with a pivotal stage on front side thereof and pivotally connected to the pivotal section;
the pivotal section having a pivotal mechanism comprising a movable rack arranged on the display section and a fixed rack arranged on the pivotal section and being pivotal with respect to the movable rack, a rotational shaft being provided between the pivotal stage and the fixed rack.

2. The rotatable monitor as in claim 1, wherein the movable rack further comprises a retainer pivotal on its center and having a locking recess on bottom end thereof, the fixed rack has corresponding insertion silt, the retainer can be selectively locked to the insertion silt by operating a top end thereof.

3. The rotatable monitor as in claim 2, wherein the movable rack comprises two retainers with top ends linked to a link beam, the link beam being driven by a slide switch to selectively lock the retainers to corresponding insertion silts.

4. The rotatable monitor as in claim 1, wherein the movable rack and the fixed rack is pivotally connected through a pivotal shaft allowing only 180-degree swing.

5. The rotatable monitor as in claim 4, wherein the pivotal shaft comprises a fixed outer shaft projecting upward from the fixed rack and a movable inner shaft projecting downward from the movable rack and into the fixed outer shaft and exposing out of the fixed outer shaft; the fixed rack having a retaining plate with a left opening and a right opening, the movable inner shaft having a semi-annulus retaining rib thereon, when the display section is not rotated, one end of the semi-annulus retaining rib abuts to one of the two openings; when the display section is rotated 180 degree, another end of the semi-annulus retaining rib abuts to another one of the two openings.

6. The rotatable monitor as in claim 1, wherein the operative section further has a locking mechanism on rear side thereof and used to lock the display section, and the display section has locking recesses on front side and back side thereof for locking to the locking mechanism.

7. The rotatable monitor as in claim 6, wherein the locking mechanism comprises a mounting rack arranged on the operative section, a link rack laterally movable with respect to the mounting rack, and two retainers between the link rack and the mounting rack, both ends of the mounting rack connected to one retainer through a pivotal post, the retainer having a top end exposing out of the operative section and having an actuating pin on bottom end thereof, the link rack having an actuating hole and an elongated guiding slot on each end thereof, the actuating pin inserting into the actuating hole and the pivotal post inserting into the elongated guiding slot, the link rack being driven by a locking switch to move.

8. The rotatable monitor as in claim 7, wherein both of the link rack and the mounting rack have a projecting section at center thereof and two shoulders, the projecting section of the link rack has a length greater than that of the projecting section of the mounting rack.

9. The rotatable monitor as in claim 7, wherein the mounting rack has two bottom plates on both sides thereof and having guiding posts, the link rack has two bottom plates on both sides thereof and having elongated bottom slots, the link rack is also moved by the linkage of the guiding posts and the elongated bottom slots.

10. A rotatable monitor comprising
a display section with a pivotal section on bottom thereof;
an operative section with a pivotal stage on front side thereof and pivotally connected to the pivotal section;
the pivotal section having a pivotal mechanism comprising a movable rack arranged on the display section and a fixed rack arranged on the pivotal section and being pivotal with respect to the movable rack, a rotational shaft being provided between the pivotal stage and the fixed rack, the display section having a monitor input through input stylus such as a light pen.

11. A rotatable monitor comprising
a display section with a pivotal section on bottom thereof;
an operative section with a pivotal stage on front side thereof and pivotally connected to the pivotal section;
the pivotal section having a pivotal mechanism comprising a movable rack arranged on the display section and a fixed rack arranged on the pivotal section and being pivotal with respect to the movable rack, a rotational shaft being provided between the pivotal stage and the fixed rack, the display section having a touch panel thereon.
